(19) United States
(12) Patent Application Publication
(10) Pub. No.: US 2025/0203829 A1
(43) Pub. Date: Jun. 19, 2025

(54) EMC HOUSING, HOUSING PART OF AN EMC HOUSING AND USE

(71) Applicant: GKN Automotive Limited, Birmingham (GB)

(72) Inventors: Tobias Weling, Lohmar (DE); Björn Nemitz, Lohmar (DE)

(21) Appl. No.: 18/956,452

(22) Filed: Nov. 22, 2024

(30) Foreign Application Priority Data
Dec. 15, 2023 (DE) DE102023135357.8

(51) Int. Cl. H05K 9/00

(52) U.S. Cl. CPC H05K 9/0047; H05K 9/0015; H05K 9/009

(57) ABSTRACT

An EMC housing for an electrical component, having a first housing part and a second housing part which are connected to one another via a sealing surface and together enclose a volume of the housing in a liquid-tight manner At least the first housing part comprises a plastic material and a metallic material enclosed by the plastic material, and the metallic material is arranged so as to be accessible at least in the region of the sealing surface for electrically conductive contacting of the second housing part.

### CROSS REFERENCE TO RELATED APPLICATIONS

This application claims the priority to German Patent Application No. DE102023135357.8 filed on Dec. 15, 2023, and the entire content of this priority application is incorporated herein by reference in its entirety.

### TECHNICAL FIELD

The disclosure relates to an EMC housing, a housing part of an EMC housing and a use of an EMC housing. The housing or the first housing part serves in particular to ensure electromagnetic compatibility (EMC) in the arrangement of an electrical component by shielding it from an environment.

### BACKGROUND

The shielding of electrical or electrotechnical components serves to keep electrical and magnetic fields away from them, particularly at higher frequencies, or conversely to protect the environment from the fields emitted by the component.

In particular, shielding is provided by electrically conductive metal sheets, foils or layers (connected to earth or reference potential or ground). These include, for example, metal-coated plastic foils, paper laminated with aluminum foil, graphite and conductive lacquer layers. It is also known to coat plastic housings with a metallic layer.

The shielding is designed in particular as a housing or housing part, whereby the housing encloses a volume in which at least one electrical component (to be shielded) is arranged. Such housings are regularly designed in several parts so that an electrically conductive connection of each individual housing part to ground or the reference potential is ensured.

A design of the housing or housing parts (exclusively) made of metal is very expensive. A design made of a plastic material is more favourable, but shielding is not achieved by the plastic material alone. Due to the application of a metallic layer on the plastic material, however, this type of housing or housing part is even more expensive than the metal housing.

In the case of multi-part housings, it is also important to ensure that the volume enclosed by the housing is at least liquid-tight (possibly even gas-tight) against the environment. If, for example, an electrically non-conductive sealing material is provided there, the electrically conductive connection of individual housing parts takes place only via connecting elements, such as screws or the like

The object of the present disclosure is to solve, at least in part, the problems cited with reference to the prior art. In particular, a housing or a housing part for a housing is to be proposed which can be produced at low cost and at the same time enables effective shielding of an electrical component.

### SUMMARY

A housing, a housing part and the use of a housing contribute to solving these problems. Advantageous further developments are the subject of the dependent claims. The features listed individually in the claims can be combined with each other in a technologically meaningful way and can be supplemented by explanatory facts from the description and/or details from the figures, whereby further embodiments of the disclosure are shown.

An EMC housing (hereinafter also referred to as ‘housing’) for an electrical component (e.g. an inverter, in particular an inverter used in a motor vehicle, a converter, etc.) is proposed. The housing comprises at least a first housing part and a second housing part, which are connected to one another via a sealing surface and together enclose a volume of the housing in a liquid-tight manner. At least the first housing part comprises a plastic material and a metallic material enclosed by the plastic material. The metallic material is arranged so as to be accessible at least in the area of the sealing surface for electrically conductive contacting of the second housing part.

The EMC housing is in particular a dimensionally stable housing, i.e. it is in particular not or only insignificantly elastic, but only plastically deformable. The same applies in particular to the first housing part.

In particular, the metallic material (as the only component of the first housing part) serves to shield the electrical component from electrical or electromagnetic radiation. In particular, the metallic material is designed (in particular thin-walled or with a low material thickness) in such a way that dimensional stability of the first housing part is at least essentially ensured by the plastic material. In particular, the plastic material thus serves to produce and maintain the desired shape of the first housing part, with the metallic material being designed or arranged to match this shape.

In particular, the metallic material is designed as a film, mesh, grid, fabric, knitted fabric or scrim. In particular, the metallic material arranged within the first housing part is arranged contiguously, so that electrically conductive contacting of one area of the metallic material also results in electrically conductive contacting of all other areas of the metallic material. Any electrically conductive material is suitable as a metallic material, especially one with an electrical conductivity between that of aluminum (as a low-cost material) and that of copper (as the material with the highest conductivity).

In particular, the metallic material is closed, i.e. it has no holes, openings or exposed areas. If holes (e.g. in the case of a perforated foil) or openings or exposed areas (e.g. in the form of a net, grid, fabric, knitted fabric or scrim) are provided, these amount to an area proportion, in relation to the total area covered by the metallic material, of at most 50%, in particular at most 25%, preferably at most 10% or even at most 1%.

In particular, the metallic material is completely enclosed by the plastic material. In particular, the metallic material is arranged within the plastic material and at a distance from the outer surfaces of the first housing part formed by the plastic material (with the exception of the area of the sealing surface).

Enclosed means in particular that the metallic material is arranged embedded in the plastic material, e.g. as a result of manufacturing the first housing part using a two-component injection moulding process, in which the metallic material is arranged encapsulated by the plastic material. In particular, the metallic material can also be partially arranged on the surface of the first housing part and thus at least partially break through or interrupt the surface of the first housing part formed by the plastic material.

In particular, the metallic material is not a coating of the plastic material.

The metallic material is arranged so as to be accessible at least (or exclusively) in the area of the sealing surface for electrically conductive contacting of the second housing part. This means in particular that the metallic material can be contacted in this area, i.e. it is not covered or concealed by the plastic material.

In particular, the sealing surface is arranged (exclusively) in the area of a contact between the first housing part and the second housing part (or another housing part). In the area of the sealing surface, the housing or the volume enclosed by the housing is sealed off from an environment of the housing (in particular liquid-tight, possibly even gas-tight). In particular, a seal or sealing material is arranged in the area of the sealing surface for this purpose.

Because the metallic material is arranged so that it is accessible, it can be electrically contacted in particular (past the plastic material). In particular, the metallic material can thus be electrically conductively connected to the second housing part (or another housing part).

In particular, contact is made between the metallic material and the second housing part via an electrically conductive EMC-seal that seals the housing parts in a liquid-tight manner.

EMC-seals are generally known. In particular, they ensure a liquid-tight or even gas-tight connection of second components, which are then electrically connected to each other via the EMC-seal itself. The EMC-seal itself is therefore electrically conductive.

In particular, the metallic material in the area of the sealing surface is accessible via a groove in the plastic material of the first housing part. In particular, the EMC-seal is arranged in this groove.

Alternatively or additionally, contact is made between the metallic material and the second housing part via a direct contact, whereby the housing parts are additionally sealed liquid-tight via a sealing element (gasket). In particular, the sealing element is not electrically conductive, i.e. it is not an EMC-seal. To create the direct contact, the metallic material can extend out of the plastic material and thus protrude towards the second housing part in the area of the sealing surface. Alternatively or additionally, a projection can be provided on the second housing part, which extends towards an accessible area of the metallic material in the first housing part.

In particular, the sealing surface extends fully circumferential around the volume. The sealing surface therefore extends in particular around the respective housing part or the (partial) volume enclosed by it. The respective seal (EMC-seal and/or the sealing element) extends in particular along the sealing surface, in particular also fully circumferentially.

In particular, the plastic material accounts for at least 60% of the weight of the first housing part, which may be at least 75%, or at least 85% or even at least 90%. If necessary, the weight proportion of the plastic material can also be more than 95% or even more than 99% or more than 99.5%.

In particular, the metallic material (with or without holes) extends contiguously over a surface portion of a largest side surface of the first housing part of at least 80%, in particular of at least 90%, or of at least 95% or even of at least 99%. The largest side surface of the first housing part is in particular the inner side facing the volume enclosed by the housing or the outer side of the first housing part facing the environment.

In particular, the first housing part is designed with a comparatively low material thickness, e.g. between 1 and 5 millimeters, in particular no more than 4 millimeters. In particular, the first housing part has a significantly greater extension transverse to the direction of the material thickness, whereby this is generally greater than at least 20 millimeters, which may be greater than 40 millimeters. In particular, the extension transverse to the direction of the material thickness is between 100 and 400 millimeters.

The largest side surface, which thus extends in particular transversely to the material thickness, comprises in particular at least 100 cm², which may be at least 150 cm², or may be at least 200 cm². In particular, the largest side area comprises at most 800 cm² or at most 600 cm².

The metallic material extends in particular continuously over the surface portion, so that all parts of the metallic material in the first housing part are electrically conductively connected to one another.

The metallic material extends in particular across the enclosed volume and at least up to the sealing surface, in particular up to the EMC seal or up to the direct contact. In particular, the metallic material does not extend beyond the sealing surface or beyond the EMC seal or beyond the direct contact, in particular at least no further than 10 millimeters, which may be no further than 5 millimeters.

In particular, the metallic material within the plastic material, possibly only outside the sealing surface, at least partially has a structured shape that deviates from a flat shape. A structured shape is, for example, a fold, e.g. zig-zag fold, a corrugation, e.g. sinusoidal, or elevations and/or depressions.

In particular, a weight proportion of the metallic material of at least 75%, in particular at least 85%, or at least 90%, may have the structured shape.

In particular, the term ‘flat shape’ refers to an area of the metallic material (e.g. the foil, the mesh, the fabric, etc.) that extends (essentially) parallel to the immediately neighbouring areas of the largest side surfaces of the first housing part.

On the one hand, the structured shape can stabilise the geometric shape of the first housing part. On the other hand, the structured shape provides a surface of the metallic material pointing in different directions, so that the electromagnetic radiation of the electrical component is reflected rather diffusely.

In particular, the first housing part is a two-component injection moulded part, whereby the metallic material is encapsulated by the plastic material.

In particular, to shield electromagnetic radiation emitted by the electrical component, the volume is completely surrounded by a metallic material that at least partially forms the housing. The metallic material (possibly also different metallic materials) is thus arranged in the first housing part and also in the second housing part (possibly also in further housing parts surrounding the volume).

Furthermore, a housing part of the described EMC housing is proposed, wherein the housing part is the first housing part.

In particular, the entire EMC housing is formed (exclusively) by a correspondingly designed plurality of first housing parts.

A use of the described EMC housing for an inverter as an electrical component is also proposed.

In particular, the EMC housing is intended for arrangement in motor vehicles, especially as a housing for an electrical component that is used in connection with a traction drive or an electrical machine of the motor vehicle.

The explanations relating to the EMC housing are particularly applicable to the first housing part and its use and vice versa.

The use of indefinite articles (‘an’, ‘a’), in particular in the claims and the description reproducing them, is to be understood as such and not as a number word. Accordingly, terms or components introduced thereby are to be understood as being present at least once and, in particular, may also be present more than once.

As a precaution, it should be noted that the number words used here (‘first’, ‘second’, . . . ) primarily serve (only) to distinguish between several similar objects, quantities or processes, i.e. in particular they do not necessarily specify any dependency and/or sequence of these objects, quantities or processes in relation to one another. If a dependency and/or sequence is required, this is explicitly stated here or is obvious to the person skilled in the art when studying the specific embodiment described. Insofar as a component may occur more than once (‘at least one’), the description of one of these components may apply equally to all or some of the majority of these components, but this is not mandatory.

### BRIEF DESCRIPTION OF THE DRAWINGS

The disclosure and the technical context are explained in more detail below with reference to the accompanying figures. It should be noted that the disclosure is not intended to be limited by the embodiments given. In particular, it should be noted that the figures and in particular the proportions shown are only schematic. The figures show:

FIG. 1 a known arrangement of an inverter and an electric motor;

FIG. 2 a side view of an inverter in section and an enlarged section;

FIG. 3 a perspective view of an inverter;

FIG. 4 a known design of a housing of an inverter in a side view in section;

FIG. 5 a first embodiment (two alternative embodiments) of a first housing part in a side view in section;

FIG. 6 a sectional side view of an EMC housing with the first housing part according to FIG. 5;

FIG. 7 a second embodiment of a first housing part in a side view in section; and

FIG. 8 a sectional side view of an EMC housing with the first housing part shown in FIG. 7.

### DETAILED DESCRIPTION

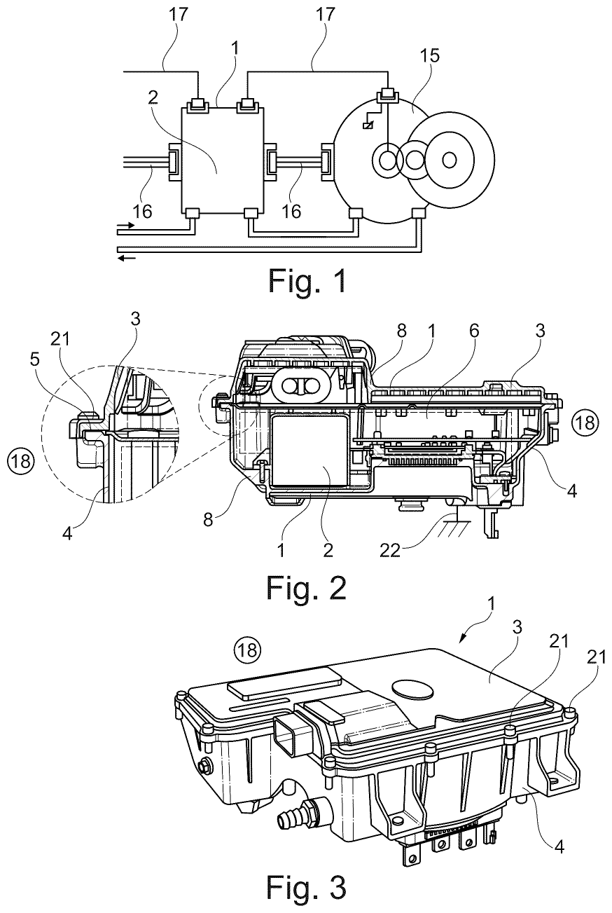

FIG. 1 shows a known arrangement of an inverter (electrical component 2) and an electric motor 15. The arrangement comprises the electrical component 2 with an EMC housing 1, the electric motor 15 and its electrical connections 16 as well as signal lines 17.

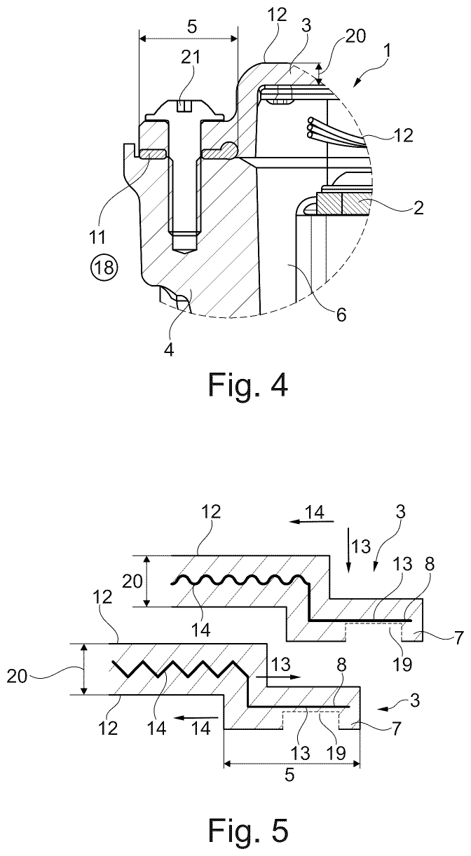

FIG. 2 shows a side view of an inverter in section and an enlarged section. FIG. 3 shows a perspective view of an inverter. FIG. 4 shows a known design of a housing 1 of an inverter in a side view in section. FIGS. 2 to 4 are described together below. Reference is made to the comments on FIG. 1.

The electrical component 2 shown here as an inverter is arranged in an EMC housing 1. The housing 1 serves to ensure electromagnetic compatibility (EMC) in the arrangement of the electrical component 2 by shielding it from an environment 18.

The shielding of electrical or electrotechnical components 2 serves to keep electrical and magnetic fields away from them, particularly at higher frequencies, or conversely to protect the environment 18 from the fields emitted by the component 2.

Shielding is provided by electrically conductive housing parts 3, 4 connected to ground 22. The housing parts 3, 4 enclose a volume 6 in which the electrical component 2 (to be shielded) is arranged. An electrically conductive connection between each individual housing part 3, 4 and the ground 22 must be ensured.

In the case of multi-part housings 1, the at least liquid-tight (possibly even gas-tight) sealing of the volume 6 enclosed by the housing 1 with respect to the environment 18 must also be observed. It is known, for example, to provide an electrically non-conductive sealing element 11 in the area of the sealing surface 5 of the housing parts 3, 4 in contact with each other, whereby the electrically conductive connection of the individual housing parts 3, 4 is then ensured, for example (only or essentially) via connecting elements 21, such as screws (see FIG. 4).

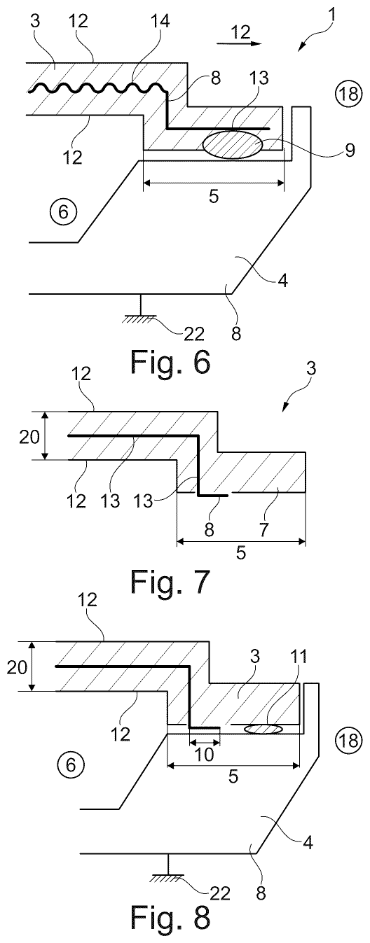

FIG. 5 shows a first embodiment (two alternative embodiments) of a first housing part 3 in a side view in section. FIG. 6 shows an EMC housing 1 with the first housing part 3 according to FIG. 5 in a side view in section. FIGS. 5 and 6 are described together below. Reference is made to the comments on FIGS. 1 to 4.

The housing 1 comprises a first housing part 3 and a second housing part 4, which are connected to each other via a sealing surface 5 and together enclose a volume 6 of the housing 1 in a liquid-tight manner. At least the first housing part 3 comprises a plastic material 7 and a metallic material 8 enclosed by the plastic material 7. The metallic material 8 is arranged so as to be accessible in the area of the sealing surface 5 for electrically conductive contacting of the second housing part 4.

The EMC housing 1 is a dimensionally stable housing that is not or only insignificantly elastic, but only plastically deformable. The same applies to the first housing part 3.

The metallic material 8 (as the only component of the first housing part 3) serves to shield the electrical component 2 from electrical or electromagnetic radiation. The metallic material 8 has thin walls or a low material thickness such that the plastic material 7 at least essentially ensures the dimensional stability of the first housing part 3. The plastic material 7 thus serves to create and maintain the desired shape of the first housing part 3, with the metallic material 8 being designed or arranged to match this shape.

The metallic material 8 can be designed as a film, mesh, grid, fabric, knitted fabric or scrim. The metallic material 8 arranged within the first housing part 3 is arranged in a contiguous manner, so that all other areas of the metallic material 8 are also in electrically conductive contact with one another when one area of the metallic material 8 makes electrically conductive contact.

The metallic material 8 is completely enclosed by the plastic material 7 (outside the accessible area in the region of the sealing surface 5). The metallic material 8 is arranged inside the plastic material 7 and at a distance from the outer surfaces of the first housing part 3 formed by the plastic material 7 (with the exception of the area of the sealing surface 5).

The metallic material 8 is only accessible in the area of the sealing surface 5 for electrically conductive contacting of the second housing part 4. In this area, the metallic material 8 can be contacted, i.e. it is not covered or concealed by the plastic material 7.

The sealing surface 5 is arranged exclusively in the area of a contact between the first housing part 3 and the second housing part 4. In the area of the sealing surface 5, the housing 1 or the volume 6 enclosed by the housing 1 is sealed off from an environment 18 of the housing 1. For this purpose, a seal designed as an EMC-seal 9 is arranged in the area of the sealing surface 5.

Contact between the metallic material 8 and the second housing part 4 is made via the electrically conductive EMC-seal 9, which seals the housing parts 3, 4. The EMC-seal 9 is itself electrically conductive.

The metallic material 8 is accessible in the area of the sealing surface 5 via a groove 19 in the plastic material 7 of the first housing part 3. The EMC-seal 9 is arranged in this groove 19.

The sealing surface 5 extends fully circumferential around the volume 6. The sealing surface 5 therefore extends around the respective housing part 3, 4 and the (partial) volume 6 enclosed by it. The EMC-seal 9 also extends all the way round the sealing surface 5. A proportion by weight of the plastic material 7 in the weight of the first housing part 3 is greater than the proportion by weight of the metallic material 8.

The metallic material 8 extends contiguously over a surface portion of a largest side surface 12 of the first housing part 3, which is approximately 95%. The largest side surface 12 of the first housing part 3 is the inner side facing the volume 6 enclosed by the housing 1 or the outer side of the first housing part 3 facing the environment 18.

The first housing part 3 is designed with a comparatively low material thickness 20. The largest side surface 12 extends transversely to the material thickness 20.

The metallic material 8 extends beyond the enclosed volume 6 and at least as far as the sealing surface 5 or as far as the EMC-seal 9. The metallic material 8 does not extend beyond the sealing surface 5, or extends beyond the EMC-seal 9 only to a small extent.

Inside the plastic material 7, but only outside the sealing surface 5, the metallic material 8 at least partially has a structured shape 14 that deviates from a flat shape 13. The ‘flat shape 13’ is the area of the metallic material 8 that extends essentially parallel to the directly neighboring areas of the largest side surfaces 12 of the first housing part 3, here for example in the area of the sealing surface 5.

FIG. 5 shows two alternative embodiments of a structured shape 14. The upper version shows a sinusoidally corrugated structure. The lower version shows a zigzag-like structure. In FIG. 6, only the structured shape 14 with the corrugation is shown.

On the one hand, the structured shape 14 can stabilize the geometric shape of the first housing part 3. On the other hand, the structured shape 14 provides a surface of the metallic material 8 pointing in different directions, so that the electromagnetic radiation of the electrical component 2 is reflected rather diffusely.

The first housing part 3 is shown as a two-component injection-molded part, with the metallic material 8 being encapsulated by the plastic material 7.

To shield electromagnetic radiation emitted by the electrical component 2, the volume 6 is completely surrounded by a metallic material 8 that at least partially forms the housing 1. The metallic material 8 is therefore arranged in the first housing part 3 and also in the second housing part 4. The second housing part 4 is formed entirely from the metallic material 8.

FIG. 7 shows a second embodiment of a first housing part 3 in a side view in section. FIG. 8 shows a sectional side view of an EMC housing 1 with the first housing part 3 according to FIG. 7. FIGS. 7 and 8 are described together below. Reference is made to the comments on FIGS. 1 to 6, in particular to the comments on FIGS. 5 and 6.

In contrast to the first embodiment, in the second embodiment the contact between the metallic material 8 and the second housing part 4 is made via a direct contact 10, whereby the housing parts 3, 4 are additionally sealed liquid-tight via a sealing element 11. The sealing element 11 is not electrically conductive, i.e. it is not an EMC-seal 9 as in FIGS. 5 and 6.

To create the direct contact 10, the metallic material 8 extends out of the plastic material 7 and is thus arranged in the area of the sealing surface 5 towards the second housing part 4, protruding from the plastic material 7.

The sealing element 11 is arranged towards the environment 18, i.e. outside the contact 10, in the area of the sealing surface 5. Alternatively, the sealing material can also be arranged towards the volume 6, i.e. inside the contact 10 in the region of the sealing surface 5.

1. An EMC housing for an electrical component, comprising at least a first housing part and a second housing part, which are connected to each other via a sealing surface and together enclose a volume of the housing in a liquid-tight manner, wherein at least the first housing part comprises a plastic material and a metallic material enclosed by the plastic material, wherein the metallic material is arranged so as to be accessible at least in the region of the sealing surface for electrically conductive contacting of the second housing part.

2. The EMC housing according to claim 1, wherein the contacting between the metallic material and the second housing part is made via an electrically conductive EMC-seal which seals the housing parts in a liquid-tight manner.

3. The EMC housing according to claim 1, wherein the contacting between the metallic material and the second housing part is made via a direct contact, wherein the housing parts are additionally sealed in a liquid-tight manner via a sealing element.

4. The EMC housing according to claim 1, wherein the sealing surface is designed to be fully circumferential around the volume.

5. The EMC housing according to claim 1, wherein a proportion by weight of the plastic material in the weight of the first housing part is at least 60%.

6. The EMC housing according to claim 1, wherein the metallic material extends continuously over a surface portion of a largest side surface of the first housing part of at least 80%.

7. The EMC housing according to claim 1, wherein the metallic material outside the sealing surface and inside the plastic material at least partially has a structured shape deviating from a flat shape.

8. The EMC housing according to claim 7, wherein a weight proportion of the metallic material of at least 75% has the structured shape.

9. The EMC housing according to claim 1, wherein the first housing part is a two-component injection moulded part, wherein the metallic material is encapsulated by the plastic material.

10. The EMC housing according to claim 1, wherein, for shielding electromagnetic radiation emitted by the electrical component, the volume is completely surrounded by a metallic material at least partially forming the housing.

11. A housing part of an EMC housing according to claim 1, wherein the housing part is the first housing part.

12. A use of an EMC housing according to claim 1 for an inverter as an electrical component.
